(19) United States
(12) Patent Application Publication
(10) Pub. No.: US 2026/0133245 A1
(43) Pub. Date: May 14, 2026

(54) SEMICONDUCTOR DEVICE

(71) Applicant: Mitsubishi Electric Corporation, Tokyo (JP)

(72) Inventors: Yukio MURAMOTO, Tokyo (JP); Kenta NAKAHARA, Tokyo (JP)

(73) Assignee: Mitsubishi Electric Corporation, Tokyo (JP)

(21) Appl. No.: 19/121,062

(22) PCT Filed: Dec. 16, 2022
(86) PCT No.: PCT/JP2022/046367

§ 371 Date: Apr. 14, 2025

(51) Int. Cl. G01R 31/27; H10W 40/20; H10W 76/10

(52) U.S. Cl. CPC G01R 31/27; H10W 40/235; H10W 76/10

(57) ABSTRACT

An object is to provide a semiconductor device capable of easily switching mounting and non-mounting of a diagnosis element at a time of manufacture. A semiconductor device includes: an insulating substrate including a front surface pattern provided to a front surface and a back surface pattern provided to a back surface; a semiconductor element mounted on the front surface pattern; a heat radiation plate incorporating the insulating substrate in a top view and bonded to the back surface pattern; a case fixed to a peripheral edge part on the heat radiation plate to house the insulating substrate and the semiconductor element; and at least one diagnosis element disposed in the case to diagnose deterioration of the semiconductor element. The diagnosis element includes a terminal. The terminal is not electrically connected to the semiconductor element.

### TECHNICAL FIELD

The present disclosure relates to a semiconductor device.

### BACKGROUND ART

Proposed conventionally is a power source apparatus including a built-in lifetime detection capacitor (corresponding to a diagnosis element) to detect a lifetime of a product (for example, refer to Patent Document 1). In a technique described in Patent Document 1, the lifetime detection capacitor is electrically connected to an inner circuit in the product to detect the lifetime of the product based on electrostatic capacitance of the lifetime detection capacitor.

### Prior Art Documents

### PATENT DOCUMENT(S)

Patent Document 1: Japanese Patent Application Laid-Open No. 2001-327162

### SUMMARY

### Problem to Be Solved by the Invention

However, in the technique described in Patent Document 1, since the lifetime detection capacitor is electrically connected to the inner circuit in the product as the diagnosis element, mounting and non-mounting of the diagnosis element cannot be easily switched at a time of manufacture.

Accordingly, an object of the present disclosure is to provide a semiconductor device capable of easily switching mounting and non-mounting of a diagnosis element at a time of manufacture.

### Means to Solve the Problem

A semiconductor device according to the present disclosure includes: an insulating substrate including a front surface pattern provided to a front surface and a back surface pattern provided to a back surface; a semiconductor element mounted on the front surface pattern; a heat radiation plate incorporating the insulating substrate in a top view and bonded to the back surface pattern; a case fixed to a peripheral edge part on the heat radiation plate to house the insulating substrate and the semiconductor element; and at least one diagnosis element disposed in the case to diagnose deterioration of the semiconductor element, wherein the diagnosis element includes an external connection terminal, and the external connection terminal is not electrically connected to the semiconductor element.

### Effects of the Invention

According to the present disclosure, presence or absence of the diagnosis element does not have influence on a product; thus, mounting and non-mounting of the diagnosis element can be easily switched at a time of manufacture.

These and other objects, features, aspects and advantages of the present disclosure will become more apparent from the following detailed description when taken in conjunction with the accompanying drawings.

### BRIEF DESCRIPTION OF DRAWINGS

FIG. 1 is a cross-sectional view of a semiconductor device according to an embodiment 1.

FIG. 2 is a graph showing a characteristic value of the semiconductor device according to the embodiment 1 and a diagnosis element included in the semiconductor device.

FIG. 3 is a cross-sectional view of a semiconductor device according to an embodiment 3.

FIG. 4 is a cross-sectional view of a semiconductor device according to an embodiment 4.

FIG. 5 is a cross-sectional view of a semiconductor device according to an embodiment 5.

### DESCRIPTION OF EMBODIMENT(S)

### Embodiment 1

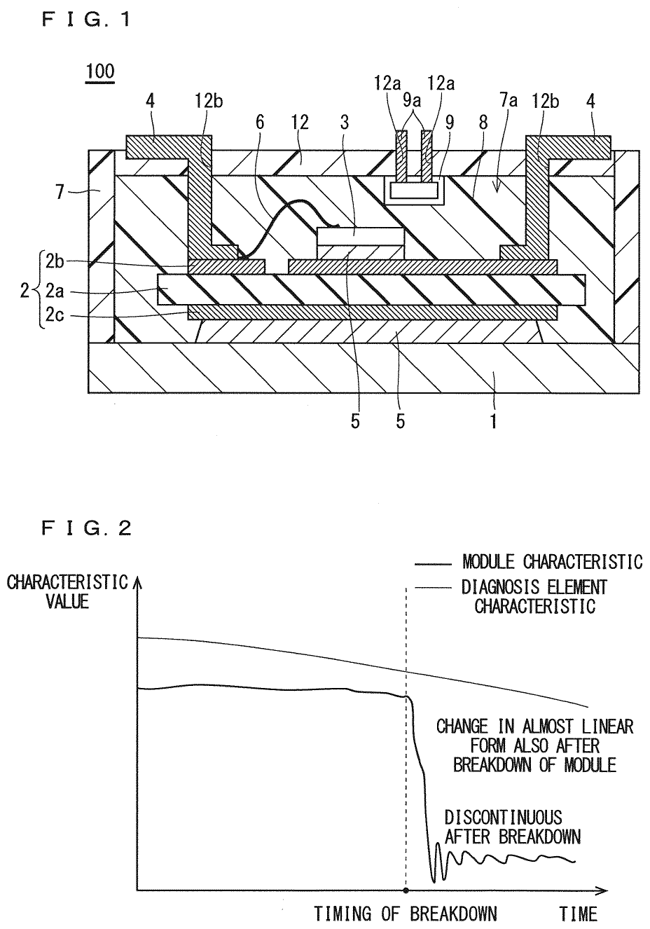

An embodiment 1 is described hereinafter using the diagrams. FIG. 1 is a cross-sectional view of a semiconductor device 100 according to the embodiment 1.

As illustrated in FIG. 1, the semiconductor device 100 is a power module, and includes a heat radiation plate 1, an insulating substrate 2, a semiconductor element 3, a plurality of lead electrodes 4, a case 7, a sealing resin 8, a diagnosis element 9, and a cover 12.

The insulating substrate 2 is formed into a rectangular shape in a top view. The insulating substrate 2 includes an insulating base member 2a, a front surface pattern 2b provided to a front surface of the insulating base member 2a, and a back surface pattern 2c provided to a back surface of the insulating base member 2a. The insulating base member 2a is formed by ceramic, for example. The front surface pattern 2b and the back surface pattern 2c are made up of metal such as copper, for example.

The heat radiation plate 1 is made up of metal such as copper, for example, to have a rectangular shape in a top view. The heat radiation plate 1 incorporates the insulating substrate 2 in a top view, and is bonded to the back surface pattern 2c by a bonding material 5. The bonding material 5 is solder, for example.

The semiconductor element 3 is mounted to the front surface of the insulating substrate 2. Specifically, the semiconductor element 3 is mounted on the front surface pattern 2b via the bonding material 5. The semiconductor element 3 is electrically connected to the lead electrode 4 by a metal wire 6. Herein, the number of semiconductor elements 3 is not limited to one, but the plurality of semiconductor elements 3 are also applicable.

The semiconductor element 3 is an insulated gate bipolar transistor (IGBT) or a metal oxide semiconductor field effect transistor (MOSFET), for example. The semiconductor element 3 may include a free wheeling diode (FWD) which is electrically connected. The semiconductor element 3 is formed of silicon or a wide bandgap semiconductor material. The wide bandgap semiconductor material is silicon carbide, a gallium nitride series semiconductor material, and diamond, for example.

The case 7 is formed into a rectangular frame-like shape in a top view. The case 7 is fixed to a peripheral edge part on the heat radiation plate 1 to house the insulating substrate 2 and the semiconductor element 3. The case 7 is formed by resin and has insulation properties.

The diagnosis element 9 is disposed on an upper part in the case 7. Specifically, the diagnosis element 9 is disposed on an upper part than the semiconductor element 3 in the case 7. The diagnosis element 9 is a member for diagnosing deterioration of the semiconductor element 3, that is to say, deterioration of the semiconductor device 100. Diagnosis of deterioration of the semiconductor device 100 is described hereinafter.

The cover 12 is attached to an upper side than the diagnosis element 9 to cover an opening 7a of the case 7. The cover 12 is formed by resin and has insulation properties in the manner similar to the case 7. Two through holes 12a and a plurality of through holes 12b are formed in the cover 12. Two terminals 9a included in the diagnosis element 9 protrude to an outer part through two through holes 12a. That is to say, two terminals 9a of the diagnosis element 9 are external connection terminals, and are not electrically connected to the semiconductor element 3. Thus, an operation of the diagnosis element 9 does not have influence on an operation of the semiconductor element 3, and an operation of the semiconductor element 3 does not also have influence on an operation of the diagnosis element 9. Since presence or absence of the diagnosis element 9 does not have influence on the semiconductor device 100 as a product, mounting and non-mounting of the diagnosis element 9 can be easily switched at a time of manufacture.

One end portions of the plurality of lead electrodes 4 are connected to the front surface pattern 2b, and the other end portions thereof protrude to an outer part through the plurality of through holes 12b formed in the cover 12, respectively. The sealing resin 8 is formed of epoxy resin, for example, and fills the case 7.

Described next using FIG. 2 is diagnosis of deterioration of the semiconductor device 100 using the diagnosis element 9. FIG. 2 is a graph showing a characteristic value of the semiconductor device 100 according to the embodiment 1 and the diagnosis element 9 included in the semiconductor device 100.

Deterioration of the semiconductor device 100 relates to deterioration of the semiconductor element 3, and it can be considered that a timing of breakdown of the semiconductor device 100 is the same as that of breakdown of the semiconductor element 3. Thus, the timing of breakdown of the semiconductor element 3 is used as the timing of breakdown of the semiconductor device 100 in diagnosis of deterioration of the semiconductor device 100. As illustrated in FIG. 2, the timing of breakdown of the semiconductor device 100 and the characteristic value of the diagnosis element 9 relate to each other. The characteristic value of the diagnosis element 9 is changed with time depending on an operation environment of the semiconductor device 100 or a temperature in driving the semiconductor device 100, for example. When the characteristic value of the diagnosis element 9 becomes a specific value, it is recognized that the semiconductor device 100 is broken down. Thus, when the characteristic value of the diagnosis element 9 is measured, the timing of breakdown of the semiconductor device 100, that is to say, deterioration of the semiconductor device 100 can be diagnosed.

Herein, a module characteristic (a characteristic of the semiconductor device 100) in FIG. 2 is output voltage of the semiconductor device 100, and is not continuous after breakdown of the semiconductor device 100. A diagnosis element characteristic in FIG. 2 is a characteristic of the diagnosis element 9, and monotonically decreases continuously before and after breakdown of the semiconductor device 100.

Although FIG. 2 illustrates a case where the characteristic value of the diagnosis element 9 monotonically decreases with time, the characteristic value of the diagnosis element 9 may monotonically increases with time. Any member is adoptable as the diagnosis element 9 as long as a characteristic value thereof relates to the timing of breakdown of the semiconductor device 100.

As a method of diagnosing deterioration of the semiconductor device 100, a module characteristic and a diagnosis element characteristic are stored in a data server (not shown), and stored data is used as mechanical learning data; thus, deterioration of the semiconductor device 100 can be diagnosed from the diagnosis element characteristic. Herein, the module characteristic is obtained from shipping test data and deterioration test data of a product and operation data in actual activation of the product.

As described above, the semiconductor device 100 according to the embodiment 1 includes the insulating substrate 2 including the front surface pattern 2b provided to the front surface and the back surface pattern 2c provided to the back surface, the semiconductor element 3 mounted on the front surface pattern 2b; the heat radiation plate 1 incorporating the insulating substrate 2 in a top view and bonded to the back surface pattern 2c; the case 7 fixed to the peripheral edge part on the heat radiation plate 1 to house the insulating substrate 2 and the semiconductor element 3; and the diagnosis element 9 disposed in the case 7 to diagnose deterioration of the semiconductor element 3, wherein the diagnosis element 9 includes the terminal 9a, and the terminal 9a is not electrically connected to the semiconductor element 3.

Since presence or absence of the diagnosis element 9 does not have influence on the semiconductor device 100 as the product, mounting and non-mounting of the diagnosis element 9 can be easily switched at the time of manufacture.

### Embodiment 2

A semiconductor device 100 according to an embodiment 2 is described next. In the description in the embodiment 2, the same reference numerals are assigned to the same constituent elements as those described in the embodiment 1, and the description thereof will be omitted.

In the embodiment 2, the diagnosis element 9 is an electrolytic capacitor, and a structure of the semiconductor device 100 and a temporal change of the characteristic value of the electrolytic capacitor are similar to the case in the embodiment 1, thus are described using FIG. 1 and FIG. 2. In the description in the embodiment 2, the diagnosis element 9 is an electrolytic capacitor.

As illustrated in FIG. 1, the electrolytic capacitor is disposed on an upper side than the semiconductor element 3 in the case 7. Two terminals 9a included in the electrolytic capacitor protrude to an outer part through two through holes 12a. That is to say, two terminals 9a of the electrolytic capacitor are external connection terminals, and are not electrically connected to the semiconductor element 3. Thus, an operation of the electrolytic capacitor does not have influence on an operation of the semiconductor element 3, and an operation of the semiconductor element 3 does not also have influence on an operation of the electrolytic capacitor. Since presence or absence of the electrolytic capacitor does not have influence on the semiconductor device 100 as a product, mounting and non-mounting of the electrolytic capacitor can be easily switched at a time of manufacture.

Although not shown in the diagrams, two terminals 9a of the electrolytic capacitor is connected to a sensor for measuring an electrostatic capacitance of the electrolytic capacitor. As illustrated in FIG. 2, the electrostatic capacitance of the electrolytic capacitor decreases with time depending on an operation environment of the semiconductor device 100 or a temperature in driving the semiconductor device 100, for example.

Herein, a module characteristic (a characteristic of the semiconductor device 100) in FIG. 2 is output voltage of the semiconductor device 100, and is not continuous after breakdown of the semiconductor device 100. A diagnosis element characteristic (a characteristic of the electrolytic capacitor) in FIG. 2 is an electrostatic capacitance of the electrolytic capacitor, and monotonically decreases continuously before and after breakdown of the semiconductor device 100.

Since a method of diagnosing deterioration of the semiconductor device 100 is similar to that of the case in the embodiment 1, the description is omitted.

As described above, in the semiconductor device 100 according to the embodiment 2, the diagnosis element 9 is the electrolytic capacitor. Thus, presence or absence of the electrolytic capacitor does not have influence on the semiconductor device 100 as a product, and mounting and non-mounting of the electrolytic capacitor can be easily switched at a time of manufacture.

### Embodiment 3

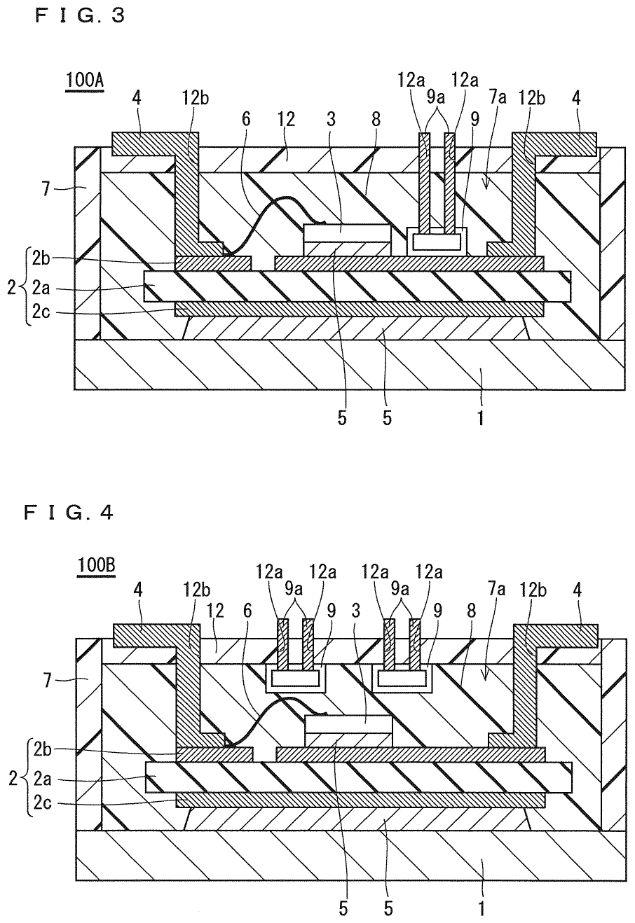

A semiconductor device 100A according to an embodiment 3 is described next. FIG. 3 is a cross-sectional view of the semiconductor device 100A according to the embodiment 3. In the description in the embodiment 3, the same reference numerals are assigned to the same constituent elements as those described in the embodiments 1 and 2, and the description thereof will be omitted.

As illustrated in FIG. 3, in the embodiment 3, the diagnosis element 9 is disposed in a surrounding part of the semiconductor element 3 on the front surface pattern 2b. Since the diagnosis element 9 is disposed near the semiconductor element 3, a diagnosis element characteristic further specifically reflecting a temperature of the semiconductor element 3 can be obtained. In the embodiment 3, the diagnosis element 9 may be an electrolytic capacitor.

As described above in the semiconductor device 100A according to the embodiment 3, the diagnosis element 9 is disposed in the surrounding part of the semiconductor element 3 on the front surface pattern 2b. Thus, the diagnosis element characteristic further specifically reflecting the temperature of the semiconductor element 3 can be obtained, and improvement of a deterioration diagnosis accuracy in the semiconductor device 100A can be expected.

### Embodiment 4

A semiconductor device 100B according to an embodiment 4 is described next. FIG. 4 is a cross-sectional view of the semiconductor device 100B according to the embodiment 4. In the description in the embodiment 4, the same reference numerals are assigned to the same constituent elements as those described in the embodiments 1 to 3, and the description thereof will be omitted.

As illustrated in FIG. 4, in the embodiment 4, the semiconductor device 100B includes the plurality of (for example, two) the diagnosis elements 9. Two terminals 9a included in each diagnosis element 9 are not electrically connected to the semiconductor element 3. Thus, the diagnosis element characteristic can be individually obtained from each diagnosis element 9.

Two diagnosis elements 9 may be disposed on an upper side than the semiconductor element 3 in the case 7, or may also be disposed in a surrounding part of the semiconductor element 3 on the front surface pattern 2b. It is also applicable that one of two diagnosis elements 9 is disposed on an upper side than the semiconductor element 3 in the case 7, and the other one thereof is disposed in a surrounding part of the semiconductor element 3 on the front surface pattern 2b.

Although two diagnosis elements 9 are provided in FIG. 4, the number of the diagnosis elements 9 is not limited to two. Three or more the diagnosis elements 9 are also applicable. In the embodiment 4, the diagnosis element 9 may be an electrolytic capacitor.

As described above, the semiconductor device 100B according to the embodiment 4 includes the plurality of diagnosis elements 9, thus, data in consideration of a plurality of diagnosis element characteristics can be used as mechanical learning data. Accordingly, improvement of a deterioration diagnosis accuracy in the semiconductor device 100B can be expected.

### Embodiment 5

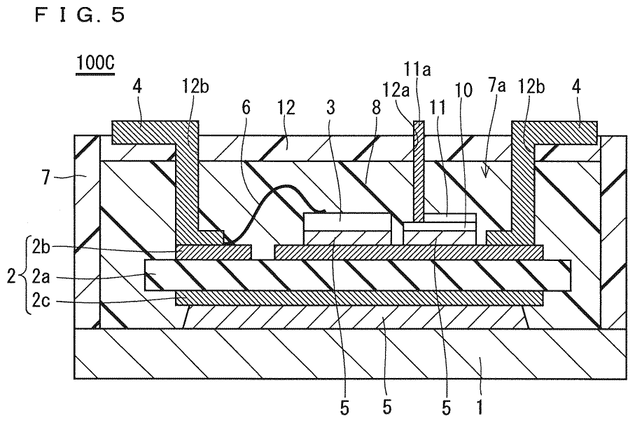

A semiconductor device 100C according to an embodiment 5 is described next. FIG. 5 is a cross-sectional view of the semiconductor device 100C according to the embodiment 5. In the description in the embodiment 5, the same reference numerals are assigned to the same constituent elements as those described in the embodiments 1 to 4, and the description thereof will be omitted.

As illustrated in FIG. 5, in the embodiment 5, the semiconductor device 100C includes a distortion gauge 11 and a detection sample 10 to which the distortion gauge 11 is attached in place of the diagnosis element 9. A gauge lead 11a of the distortion gauge 11 is an external connection terminal, and the gauge lead 11a protrudes to an outer part through the through hole 12a. That is to say, the gauge lead 11a of the distortion gauge 11 is not electrically connected to the semiconductor element 3. Thus, an operation of the distortion gauge 11 does not have influence on an operation of the semiconductor element 3, and an operation of the semiconductor element 3 does not also have influence on an operation of the distortion gauge 11. In this manner, since presence or absence of the distortion gauge 11 does not have influence on the semiconductor device 100C as a product, mounting and non-mounting of the distortion gauge 11 can be easily switched at a time of manufacture.

The detection sample 10 is bonded on the front surface pattern 2b by the bonding material 5. The detection sample 10 is preferably bonded to the surrounding part on the front surface pattern 2b to obtain the diagnosis element characteristic further specifically reflecting the temperature of the semiconductor element 3.

The detection sample 10 is preferably made up of a material having a larger linear expansion coefficient than that of the insulating substrate 2 to clearly grasp a thermal history. Since the detection sample 10 needs to function also in breakdown of the semiconductor device 100C, bonding between the detection sample 10 and the insulating substrate 2 needs to have higher durability than bonding between the semiconductor element 3 and the meatal wire 6 and bonding between the insulating substrate 2 and the heat radiation plate 1. The durability between the detection sample 10 and the insulating substrate 2 can be adjusted by changing a shape and a bonding area of the detection sample 10.

The detection sample 10 is extended and shrunk depending on an operation environment of the semiconductor device 100C or a temperature in driving the semiconductor device 100C, for example. Distortion of the detection sample 10 is accumulated with time, and the accumulated distortion of the detection sample 10 is measured by the distortion gauge 11. The distortion of the detection sample 10 measured by the distortion gauge 11 is used as a diagnosis element characteristic, and deterioration of the semiconductor device 100C is diagnosed by a method similar to the case in the embodiment 1. Herein, the distortion gauge 11 and the detection sample 10 may be provided to a plurality of positions.

It is also applicable that the detection sample 10 is not bonded on the front surface pattern 2b, but the distortion gauge 11 is directly attached on the front surface pattern 2b. In this case, the distortion of the front surface pattern 2b measured by the distortion gauge 11 is used as the diagnosis element characteristic. The distortion gauge 11 may be provided to a plurality of positions.

It is also applicable that the gauge lead 11a is not an external connection terminal, but an external connection terminal is separately provided, and the gauge lead 11a is connected to the external connection terminal as the other member.

As described above, in the semiconductor device 100C according to the embodiment 5, the diagnosis element 9 is the distortion gauge 11, and the external connection terminal is connected to the gauge lead 11a of the distortion gauge 11.

Since presence or absence of the distortion gauge 11 does not have influence on the semiconductor device 100C as a product, mounting and non-mounting of the distortion gauge 11 can be easily switched at a time of manufacture.

The diagnosis element 9 includes the detection sample 10 to which the distortion gauge 11 is attached, the detection sample 10 is disposed on the front surface pattern 2b, and the external connection terminal is the gauge lead 11a.

Since the distortion of the detection sample 10 is used as the diagnosis element characteristic, improvement of a deterioration diagnosis accuracy in the semiconductor device 100C can be expected compared with the case where the distortion of the front surface pattern 2b is used as the diagnosis element characteristic.

Although the present disclosure is described above in detail, the foregoing description is in all aspects illustrative and does not restrict the disclosure. It is therefore understood that numerous modifications not exemplified can be devised.

Each embodiment can be arbitrarily combined, or each embodiment can be appropriately varied or omitted.

### EXPLANATION OF REFERENCE SIGNS

1 heat radiation plate, 2 insulating substrate, 2b front surface pattern, 2c back surface pattern, 3 semiconductor element, 7 case, 9 diagnosis element, 9a terminal, 10 detection sample, 11 distortion gauge, 11a gauge lead, 100, 100A, 100B, 100C semiconductor device.

1. A semiconductor device, comprising:
an insulating substrate including a front surface pattern provided to a front surface and a back surface pattern provided to a back surface;
a semiconductor element mounted on the front surface pattern;
a heat radiation plate incorporating the insulating substrate in a top view and bonded to the back surface pattern;
a case fixed to a peripheral edge part on the heat radiation plate to house the insulating substrate and the semiconductor element; and
at least one diagnosis element disposed in the case to diagnose deterioration of the semiconductor element, wherein
the diagnosis element includes an external connection terminal, and
the external connection terminal is not electrically connected to the semiconductor element.

2. The semiconductor device according to claim 1, wherein
the diagnosis element is disposed in a surrounding part of the semiconductor element on the front surface pattern.

3. The semiconductor device according to claim 1, comprising
the plurality of diagnosis elements.

4. The semiconductor device according to claim 1, wherein
the diagnosis element is an electrolytic capacitor.

5. The semiconductor device according to claim 1, wherein
the diagnosis element is a distortion gauge, and
the external connection terminal is connected to a gauge lead of the distortion gauge.

6. The semiconductor device according to claim 5, wherein
the diagnosis element includes a detection sample to which the distortion gauge is attached,
the detection sample is disposed on the front surface pattern, and
the external connection terminal is the gauge lead.

7. The semiconductor device according to claim 2, comprising
the plurality of diagnosis elements.

8. The semiconductor device according to claim 2, wherein
the diagnosis element is an electrolytic capacitor.

9. The semiconductor device according to claim 3, wherein
the diagnosis element is an electrolytic capacitor.

10. The semiconductor device according to claim 7, wherein
the diagnosis element is an electrolytic capacitor.

11. The semiconductor device according to claim 2, wherein
the diagnosis element is a distortion gauge, and
the external connection terminal is connected to a gauge lead of the distortion gauge.

12. The semiconductor device according to claim 3, wherein
the diagnosis element is a distortion gauge, and
the external connection terminal is connected to a gauge lead of the distortion gauge.

13. The semiconductor device according to claim 7, wherein
the diagnosis element is a distortion gauge, and
the external connection terminal is connected to a gauge lead of the distortion gauge.

14. The semiconductor device according to claim 11, wherein
the diagnosis element includes a detection sample to which the distortion gauge is attached,
the detection sample is disposed on the front surface pattern, and
the external connection terminal is the gauge lead.

15. The semiconductor device according to claim 12, wherein
the diagnosis element includes a detection sample to which the distortion gauge is attached,
the detection sample is disposed on the front surface pattern, and
the external connection terminal is the gauge lead.

16. The semiconductor device according to claim 13, wherein
the diagnosis element includes a detection sample to which the distortion gauge is attached,
the detection sample is disposed on the front surface pattern, and
the external connection terminal is the gauge lead.
